(19) United States
(12) Patent Application Publication
(10) Pub. No.: US 2025/0336585 A1
(43) Pub. Date: Oct. 30, 2025

(54) Electronic Component

(71) Applicant: SUMIDA CORPORATION, Tokyo (JP)

(72) Inventors: Kei TANAKA, Natori City (JP); Asami MURAKAMI, Natori City (JP)

(21) Appl. No.: 19/260,574

(22) Filed: Jul. 6, 2025

Related U.S. Application Data
(63) Continuation of application No. PCT/JP2023/004955, filed on Feb. 14, 2023.

(51) Int. Cl. H01F 27/06

(52) U.S. Cl. CPC H01F 27/06

(57) ABSTRACT

An electronic component includes a base portion having an accommodating portion that accommodates an electronic element and a terminal. The terminal has a part embedded in the base portion, and one end portion of the terminal protrudes from the base portion toward outside of the base portion. The base portion has a covering portion. The covering portion extends from an outer surface of the base portion and covers at least a part of a periphery of a base end in the one end portion of the terminal.

### CROSS REFERENCE TO RELATED APPLICATIONS

This application claims priority to Japanese Patent Application No. PCT/JP2023/004955, filed on Feb. 14, 2023, which is expressly incorporated herein by reference in its entirety.

### TECHNICAL FIELD

The present invention relates to an electronic component.

### BACKGROUND ART

Some electronic components have a base portion in which an electronic element such as a coil is accommodated, with a part of a terminal being embedded in the base portion and another part of the terminal protruding from the base portion.

With regard to this type of technique, Japanese Patent Laid-Open No. 2020-047473 (Patent Document 1) describes a vehicular glass module (1) in which terminals (glass-side conductors (7) in Patent Document 1) extend from side surfaces of end portions in a longitudinal direction of a base portion (body (10) in Patent Document 1).

When an external force is applied to an electronic component mounted on a substrate, stress concentrates in a part of a base portion surrounding a base end of a terminal that is protruding. For example, stress may concentrate at a corner that is an opening end of a depressed portion of the base portion that is formed for the terminal to be embedded.

Due to the stress concentration, problems such as destruction of the base portion and deformation of the terminal occur.

The present invention has been made in view of the problems described above and provides an electronic component which prevents a base portion from being destroyed or suppresses deformation of a terminal when an external force is applied to the electronic component.

### SUMMARY

An electronic component according to the present invention is an electronic component including a base portion having an accommodating portion that accommodates an electronic element and a terminal of which a part is embedded in the base portion and of which one end portion protrudes toward outside of the base portion from the base portion, wherein the base portion has a covering portion that extends from an outer surface of the base portion and covers at least a part of a periphery of a base end in the one end portion.

The base end of one end portion of the terminal that is protruding is covered by the covering portion extending from the base portion. Therefore, stress on the base portion when an external force is applied to the electronic component is applied in a dispersed manner from a base end to a leading end of the covering portion. As a result, when an external force is applied to the electronic component, the base portion is prevented from being destroyed or deformation of the terminal is suppressed.

### Effect of the Invention

The electronic component according to the present invention can prevent a base portion from being destroyed or suppress deformation of a terminal when an external force is applied to the electronic component.

### BRIEF DESCRIPTION OF THE DRAWINGS

The object described above as well as other objects, features, and advantages will be further clarified by the preferred embodiments described below and the following accompanying drawings, in which:

FIG. 1 is a perspective view showing an example of an electronic component according to a first embodiment of the present invention. A contour of an accommodating portion is illustrated by a dotted line.

FIG. 2 is a perspective view of the electronic component according to the first embodiment. However, a case portion and a base portion are not illustrated and only a contour is depicted by a dotted line for the base portion.

FIG. 3 is a side view of the electronic component according to the first embodiment. Contours of terminals embedded in the base portion, a shape of a plug connecting portion, a shape of a pin, and a contour of the accommodating portion are illustrated by dotted lines.

FIG. 4 is a front view of the electronic component according to the first embodiment.

FIG. 5 is a rear view of the electronic component according to the first embodiment.

FIG. 6 is a top view of the electronic component according to the first embodiment.

FIG. 7 is a bottom view of the electronic component according to the first embodiment.

FIG. 8A is an enlarged view of a covering portion and a vicinity thereof in FIG. 4. However, a mounting portion and an erected portion that are parts of the terminal are not illustrated. FIG. 8B is an enlarged view of the terminal and a vicinity thereof in FIG. 3.

FIG. 9A is a side view showing an example of an electronic component according to a second embodiment of the present invention. FIG. 9B is a front view of the electronic component. However, a mounting portion and an erected portion that are parts of the terminal are not illustrated.

FIG. 10A is a side view showing another example of the electronic component according to the second embodiment of the present invention. FIG. 10B is a front view of the electronic component. However, a mounting portion and an erected portion that are parts of a terminal are not illustrated.

FIG. 11A is a diagram illustrating a result of calculating stress applied to a contrast electronic component. FIG. 11B is a diagram illustrating a result of calculating stress applied to an electronic component. Terminals are not illustrated in FIGS. 11A and 11B.

### DETAILED DESCRIPTION

Various constituent elements of an electronic component according to the present invention need not be individually independent. A plurality of constituent elements may be formed as a single member, a single constituent element may be formed by a plurality of members, a given constituent element may constitute a part of another constituent element, a part of a given constituent element and a part of another constituent element may overlap with each other, and the like.

Hereinafter, embodiments of the present invention will be described based on the drawings. In the respective drawings, corresponding constituent elements will be denoted by common reference signs and redundant descriptions will not be repeated.

In the present embodiments, descriptions will be given by defining directions of front, rear, left, right, up and down as shown. However, the directions are merely set for the sake of convenience for explaining relative relationships among the constituent elements in a simple manner and are not intended to limit directions during manufacture or during use of products that implement the present invention. In this case, an up-down direction refers to an exemplary direction of gravitational force when mounting an electronic component to a substrate and does not necessarily mean the direction of gravitational force when using an electronic component mounted to a vehicle or the like. In other words, the direction of gravitational force of the electronic component when mounted to a vehicle or the like is not limited to the up-down direction and may include a component in a left-right direction or a component in a front-rear direction. In addition, the electronic component may be mounted with a direction other than the up-down direction as a direction of gravitational force.

The front-rear direction coincides with a longitudinal direction of the base portion, the left-right direction coincides with a transverse direction or a width direction of the base portion, and the up-down direction coincides with a height direction of the base portion. Furthermore, a direction from an outer edge toward a center of the base portion will be referred to as inward, inner side or inside and a direction from the center toward the outer edge of the base portion will be referred to as outward, outer side or outside.

Moreover, the term “flat surface” as used in the present invention means a shape having been physically formed with a flat surface as a goal and, obviously, the shape need not be geometrically perfectly flat.

### First Embodiment

### (Electronic Component)

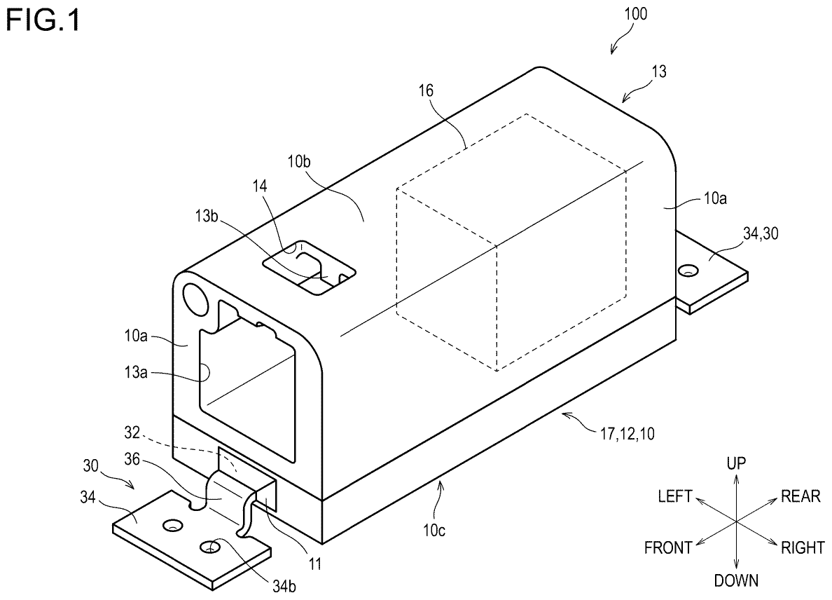

FIG. 1 is a perspective view showing an example of an electronic component 100 according to a first embodiment of the present invention.

First, an overview of the electronic component 100 according to the present embodiment will be described.

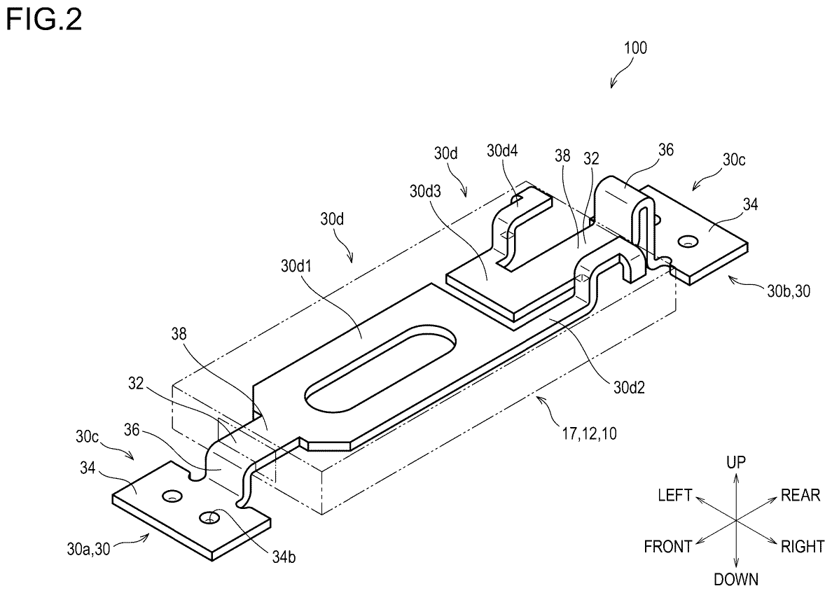

The electronic component 100 has a base portion 10 and terminals 30. The base portion 10 has an accommodating portion 16 that accommodates an electronic element. Each terminal 30 has a part (embedded portion 38 to be described later) embedded in the base portion 10, and one end portion (exposed end portion 30c to be described later (refer to FIG. 2)) protrudes from the base portion 10 toward outside of the base portion 10. The base portion 10 has covering portions 11 that extend from an outer surface of the base portion 10 and cover at least a part of a periphery of a base end in the one end portion (exposed end portion 30c).

When the base end of the one end portion of the terminal 30 that is protruding is covered by each of the covering portions 11 extending from the base portion 10, stress on the base portion 10 when an external force is applied to the electronic component 100 is applied in a dispersed manner from a base end to a leading end of the covering portion 11. In particular, the stress is applied in a dispersed manner to the leading end of the covering portion 11 and the base end of the covering portion 11 (a boundary between the covering portion 11 of the base portion 10 and a body portion 12 to be described later). Accordingly, even when an external force is applied to the electronic component 100, the base portion 10 is prevented from being destroyed or deformation of the terminal 30 is suppressed.

Next, the electronic component 100 according to the present embodiment will be described in detail.

The electronic component 100 is a component that constitutes a part of an electronic circuit. While an electronic element is included in the accommodating portion 16 to be described later in the present embodiment, the electronic element is not limited thereto. The electronic component 100 may be provided as an electronic element accommodating case without an electronic element included in the accommodating portion 16. For example, the electronic element constitutes an electronic circuit. The electronic element may include a coil. The electronic component 100 including the electronic element may function as a coil component of an inductor, a transformer, an antenna, or the like. The electronic component 100 according to the present embodiment is an electronic component 100 to be mounted on a vehicle. Examples of locations where the electronic component 100 is mounted include a vehicle body such as an interior wall portion, a window glass, a ceiling, a top of a floor, or a bottom of the floor, a part of the inside of a console box or a trunk compartment, or the inside of a device arranged at such locations. The electronic component 100 may be mounted in any orientation at any desired location in the vehicle.

The base portion 10 refers to a pedestal portion in which the terminals 30 to be described later are embedded and held. The base portion 10 is formed of an insulating material such as resin. Examples of the resin include polyphenylene sulfide (PPS). The base portion 10 is formed by injection molding. More specifically, the base portion 10 is formed by pouring a liquid insulating material into a mold within which the terminals 30 having been bent are placed and solidifying the insulating material. The following description assumes that the base portion 10 has been formed using resin as the insulating material.

In the present embodiment, a shape of the base portion 10 is an approximately rectangular parallelopiped that is elongated in the front-rear direction. The shape of the base portion 10 is not limited thereto and may be any shape such as a polygonal column or a cylindrical column. The base portion 10 is formed by a side surface 10a facing toward a side of the base portion 10 (an orientation toward either the front-rear direction or the left-right direction from a center of the base portion 10), a top surface 10b facing upward (a top surface of a case portion 13 to be described later), and a bottom surface 10c facing downward (a bottom surface of a bottom portion 17 to be described later). The side surface 10a of the base portion 10 refers to a surface formed by joining the side surface of the case portion 13 and the side surface of the bottom portion 17 to be described later. The outer surface of the base portion 10 refers to an outer surface of the body portion 12 to be described later and includes the side surface 10a, the top surface 10b, and the bottom surface 10c of the base portion 10. A surface of the covering portion 11 to be described later is not included in the outer surface of the base portion 10. It is assumed that the outer surface of the body portion 12 is also virtually arranged at a base end of the covering portion 11 to be described later. In other words, a boundary surface between the covering portion 11 and the body portion 12 is included in the outer surface of the body portion 12.

In the present embodiment, the base portion 10 includes the case portion 13 on an upper side and the bottom portion 17 on a lower side. The case portion 13 and the bottom portion 17 are bonded by an adhesive such as epoxy resin. The base portion 10 may be constituted of two or more members or, as an alternative to the present embodiment, integrally formed by one member.

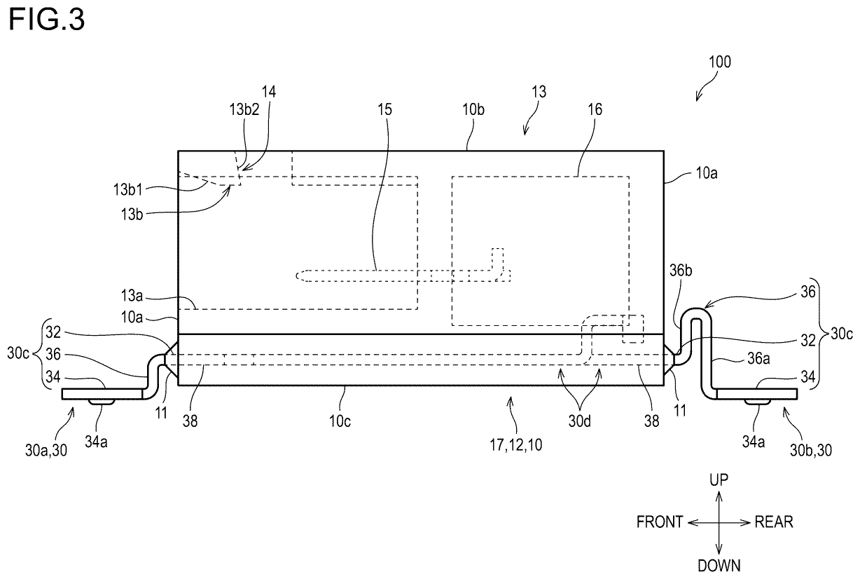

The base portion 10 (case portion 13) includes the accommodating portion 16. The accommodating portion 16 is a portion where the electronic element (not shown in the drawings) is accommodated, which may be a hollow space or a solid portion made of an insulation material. As illustrated in FIG. 3, a part of a pin 15 and a part of the terminals 30 (first terminal 30a and second terminal 30b) to be described later are inserted inside the accommodating portion 16 and connected to the electronic element inside the accommodating portion 16. In other words, the pin 15 and the terminals 30 to be described later are electrically connected via the electronic element inside the accommodating portion 16. In the present embodiment, the accommodating portion 16 is arranged on a rear side of the base portion 10 and the inside of the accommodating portion 16 and the outside of the accommodating portion 16 are integrally formed. In other words, in the present embodiment, the electronic element is embedded in the case portion 13 to be described later including the accommodating portion 16. As an alternative to the present embodiment, a space such as a depressed portion that accommodates the electronic element may be provided as the accommodating portion 16 inside the electronic component 100 and the electronic element may be arranged in the space. The electronic element may be held in the electronic component 100 that is an electronic component case by having a periphery of the electronic element being covered by a lid or the like or having the electronic element and the base portion 10 being engaged or bonded to each other.

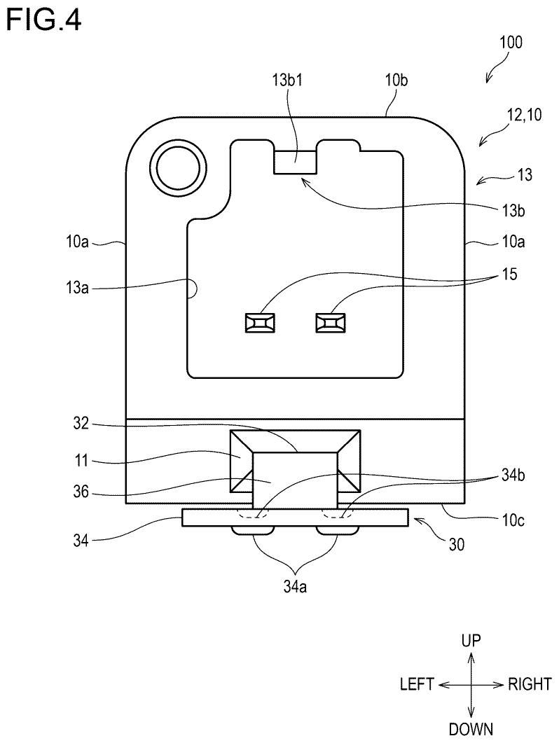

The base portion 10 (case portion 13) is provided with a plug connecting portion 13a. The plug connecting portion 13a is a portion for fixing, to the electronic component 100, a plug (not shown in the drawings) to be connected to an external circuit. In the present embodiment, the plug connecting portion 13a is formed as a bottomed depressed portion (also referred to as a plug insertion hole 13a) that opens toward the front and extends in the front-rear direction. As illustrated in FIGS. 3 and 4, a plug engagement protruding portion 13b is provided on a peripheral wall that demarcates the plug insertion hole 13a. An outer surface of the plug engagement protruding portion 13b includes an insertion surface 13b1 that faces toward the front (an opening side of plug insertion hole 13a) and an engagement surface 13b2 that faces toward the rear (a bottom portion side of plug insertion hole 13a). The engagement surface 13b2 opposes an inner side of a through-hole 14 to be described later. In addition, the engagement surface 13b2 is smoothly connected to a part of a peripheral wall that demarcates the through-hole 14 without a step.

As illustrated in FIG. 3, in the present embodiment, while the plug engagement protruding portion 13b extends in the front-rear direction, the plug engagement protruding portion 13b may be divided into a forward portion and a rearward portion by the through-hole 14. In addition, as illustrated in FIG. 4, in the present embodiment, the plug engagement protruding portion 13b is formed at center in the left-right direction in an upper part of the peripheral wall of the plug insertion hole 13a.

In the present embodiment, the plug is inserted into and fixed by the plug connecting portion 13a illustrated in FIG. 3. More specifically, the plug is inserted into the plug insertion hole 13a along the plug engagement protruding portion 13b with a shape that corresponds to an external shape of the plug. When the plug is inserted to a predetermined depth in the plug insertion hole 13a, a protruding portion provided on an outer periphery of the plug and the plug engagement protruding portion 13b engage with each other. Once the plug is inserted, due to an outer surface of a protruding portion provided on the plug and the engagement surface 13b2 of the plug engagement protruding portion 13b opposing each other and coming into pressurized contact or into contact, the plug is locked and prevented from exiting the plug insertion hole 13a.

In the present embodiment, an inclination of the insertion surface 13b1 with respect to a horizontal plane (surface parallel to front-rear direction and left-right direction) is smaller than an inclination of the engagement surface 13b2. Accordingly, the plug is readily inserted into the plug insertion hole 13a and less likely to be pulled out from the plug insertion hole 13a.

In the present embodiment, the through-hole 14 is provided on the peripheral wall that demarcates the plug insertion hole 13a and the inside of the plug insertion hole 13a and the outside of the plug insertion hole 13a are communicated via the through-hole 14. The engagement of the plug with the plug engagement protruding portion 13b can be checked visually or the like via the through-hole 14.

The plug fixed to the plug connecting portion 13a is electrically connected to the pin 15 that protrudes from the bottom portion of the plug insertion hole 13a toward inside of the plug insertion hole 13a. The pin 15 is formed of a conductive material and the plug and the electronic element are electrically connected via the pin 15.

The terminals 30 are members formed of a conductive material. Examples of the conductive material include metals such as copper. The electronic component 100 is mounted to a substrate (not shown in the drawings) by having the terminals 30 bonded to the substrate. In this case, the substrate may be a circuit board provided on glass such as a window glass for a vehicle or a circuit board provided inside a component or a device.

While the terminals 30 in the present embodiment are formed by bending a plate-like member of which a cross-sectional shape is a rectangle as will be described later, the cross-sectional shape of the terminals 30 is not limited thereto. For example, the cross-sectional shape of the terminals 30 may be circular or elliptical. In the present embodiment, as the terminals 30, the electronic component 100 has two terminals that form a pair, the first terminal 30a and the second terminal 30b, which are separated from each other in the front-rear direction. As will be described later, the first terminal 30a and the second terminal 30b differ from each other in shapes of an erected portion 36. The base portion 10 may have three or more terminals 30.

Each of the terminals 30 includes the embedded portion 38 that is embedded in the base portion 10 (particularly, in the body portion 12 to be described later), a protruding portion 32 that is contiguous with the embedded portion 38 and protrudes from an outer surface, the erected portion 36, and a mounting portion 34. The protruding portion 32, the erected portion 36, and the mounting portion 34 may be collectively referred to as an exposed end portion 30c.

The embedded portion 38 refers to at least a part of a portion that is embedded in the base portion 10 in another end portion on an opposite side to one end where the mounting portion 34 is arranged in the terminal 30 and that is arranged closest to the mounting portion 34. In the present embodiment, the other end portion (embedded end portion 30d) on the opposite side to the mounting portion 34 is embedded in the base portion 10 over its entirety from the embedded portion 38 to the other end (the end on an opposite side to the mounting portion 34). A part of the embedded end portion 30d may be exposed from the base portion 10. Respective dimensions of the embedded portion 38 in the left-right direction and the up-down direction are equal to respective dimensions of the protruding portion 32 to be described later in the left-right direction and the up-down direction. In other words, a shape and dimensions of a cross-section of the embedded portion 38 are the same as a shape and dimensions of a cross-section of the protruding portion 32.

The exposed end portion 30c has the protruding portion 32. The protruding portion 32 is a part of the exposed end portion 30c, positioned on a base end side (other end side) of the exposed end portion 30c and extends in a protruding direction of the exposed end portion 30c. In the present embodiment, the protruding portion 32 extends along a mounting surface of the electronic component 100, the mounting surface being described later. In this case, the protruding direction of the exposed end portion 30c is a direction in which a part of the base end of the exposed end portion 30c protrudes toward the outside of the base portion 10 from inside the base portion 10. In other words, in the present embodiment, the protruding direction of the exposed end portion in the first terminal 30a is a forward orientation and the protruding direction of the exposed end portion 30c in the second terminal 30b is a rearward orientation. While the protruding direction of the exposed end portion 30c in the present embodiment is an orientation parallel to the front-rear direction, the protruding direction is not limited thereto. The protruding direction of the exposed end portion 30c may be an orientation that includes a front-rear direction component or a left-right direction component and that is not parallel to the front-rear direction or the left-right direction.

In this case, a base end in the exposed end portion 30c refers to a side close to the outer surface of the base portion 10 and a root side of the protruding exposed end portion 30c. A leading end of the exposed end portion 30c refers to an end on an opposite side to the base end of the exposed end portion 30c and is an end of which a distance from the base portion 10 along the outer surface of the exposed end portion 30c is long.

In addition, in the present embodiment, a length of the protruding portion 32 in the protruding direction of the protruding portion 32 is smaller than a height at which the protruding portion 32 is arranged. In this case, the height at which the protruding portion 32 is arranged refers to a height of a lower surface of the protruding portion 32 with respect to a lower surface of the mounting portion 34. More specifically, the length of the protruding portion 32 is smaller than the length of the erected portion 36 in the first terminal 30a. In this case, the length of the protruding portion 32 or the erected portion 36 refers to a length of an approximately linear portion in the protruding portion 32 or the erected portion 36. In other words, the length of the protruding portion 32 refers to a distance from the outer surface of the base portion 10 to a boundary surface between the protruding portion 32 and a bent portion of a boundary between the protruding portion 32 and the erected portion 36. The length of the erected portion 36 refers to a distance from a boundary surface between the erected portion 36 and a bent portion of a boundary between the protruding portion 32 and the erected portion 36 to a boundary surface between the erected portion 36 and a bent portion of a boundary between the mounting portion 34 and the erected portion 36. Making the length of the protruding portion 32 smaller than the height of the protruding portion 32 enables a proportion of a portion (embedded end portion 30d) to be embedded in the base portion 10 in the terminal 30 to be increased and enables deformation of the terminal 30 to be suppressed.

As an alternative to the present embodiment, the length of the protruding portion 32 may be made larger than the height at which the protruding portion 32 is arranged. Ensuring a large length of the protruding portion 32 allows the protruding portion 32 to bend moderately when an external force is applied to the electronic component 100 and enables deformation of the terminal 30 or the base portion 10 to be suppressed.

As an alternative to the present embodiment, the terminal 30 may protrude from the bottom surface of the base portion 10. The protruding direction of the terminal 30 in this case may be a downward orientation. In this case, the downward orientation means an orientation with an up-down direction component and includes an orientation that is parallel to the up-down direction but is not limited to an orientation that is parallel to the up-down direction.

The erected portion 36 is an integrally formed portion continuous with the protruding portion 32 and extends in an orientation with an up-down direction component. While the erected portion 36 extends in an orientation parallel to the up-down direction in the present embodiment, the erected portion 36 is not limited thereto. The erected portion 36 may be inclined with respect to the up-down direction so that an upper end is on an inward side of the base portion 10 and a lower end is on an outward side of the base portion 10 or inclined with respect to the up-down direction so that the upper end is on the outward side of the base portion 10 and the lower end is on the inward side of the base portion 10.

The terminal 30 is bent between the erected portion 36 and the protruding portion 32. In the present embodiment, a bent portion located between the erected portion 36 and the protruding portion 32 is disposed outside the base portion 10 and is exposed from the base portion 10. In the present embodiment, while an angle formed by a part of the terminal 30 from the erected portion 36 to the protruding portion 32 is 90 degrees, the angle may be larger or smaller than 90 degrees.

As illustrated in FIG. 3, the erected portion 36 in the second terminal 30b includes a first erected portion 36a and a second erected portion 36b that extend in the up-down direction, respectively. A boundary between the first erected portion 36a and the second erected portion 36b are bent so that the boundary is convex in the upward direction. A dimension of the first erected portion 36a in the up-down direction is larger than a dimension of the second erected portion 36b in the up-down direction. The first erected portion 36a and the second erected portion 36b are along with each other and distanced from each other.

The mounting portion 34 is a portion to which a circuit on a substrate (not shown in the drawings) and each of the terminals 30 are connected when mounting the electronic component 100 to the substrate. Since the electronic component 100 according to the present embodiment is surface-mounted to the substrate, the mounting portion 34 has a lower surface (mounting surface) that faces downward. As an alternative to the present embodiment, the mounting portion 34 may have a pin shape and the terminal 30 may be a pin terminal. The mounting portion 34 and the substrate are joined to each other by soldering or the like as will be described later.

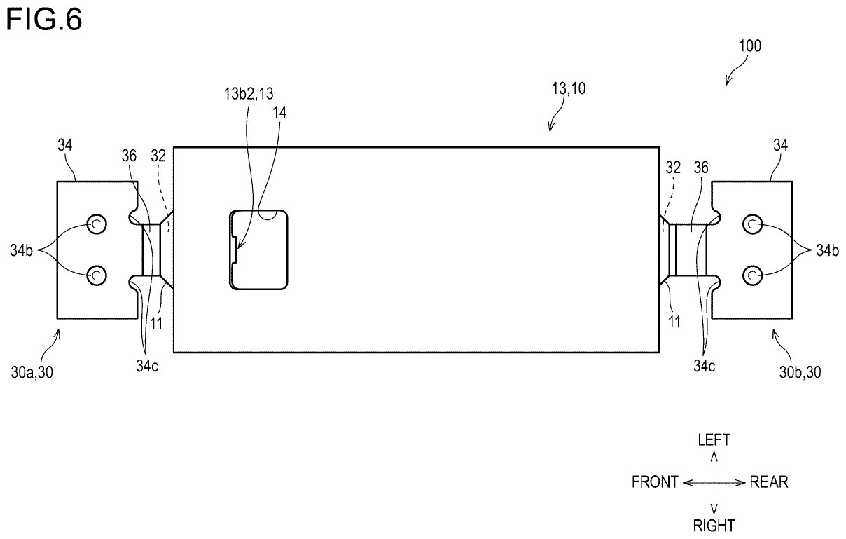

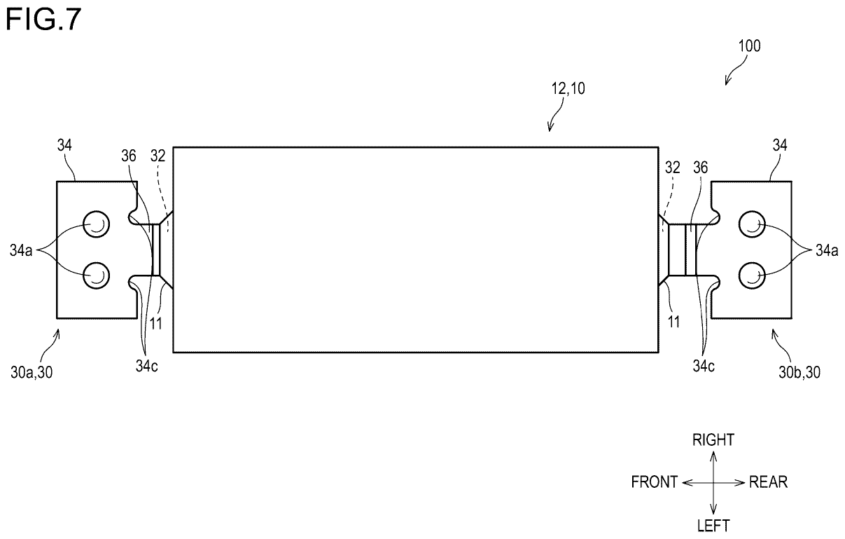

As illustrated in FIG. 6 or 7, a width dimension (dimension in the left-right direction) of the mounting portion 34 in the present embodiment is larger than a width dimension of the erected portion 36 or a width dimension of the protruding portion 32. A contour of the mounting portion 34 as viewed in the height direction is a rectangle elongated in the left-right direction. In addition, parts adjacent in the left-right direction to a part adjacent to the erected portion 36 in the mounting portion 34 (a part at center in the left-right direction in a part on a base end side of the mounting portion 34) have recessed portions 34c that are recessed in a predetermined orientation. Specifically, the recessed portions 34c are recessed in a bending direction of a bent portion of the boundary between the mounting portion 34 and the erected portion 36 (sideward and outward orientation in front-rear direction).

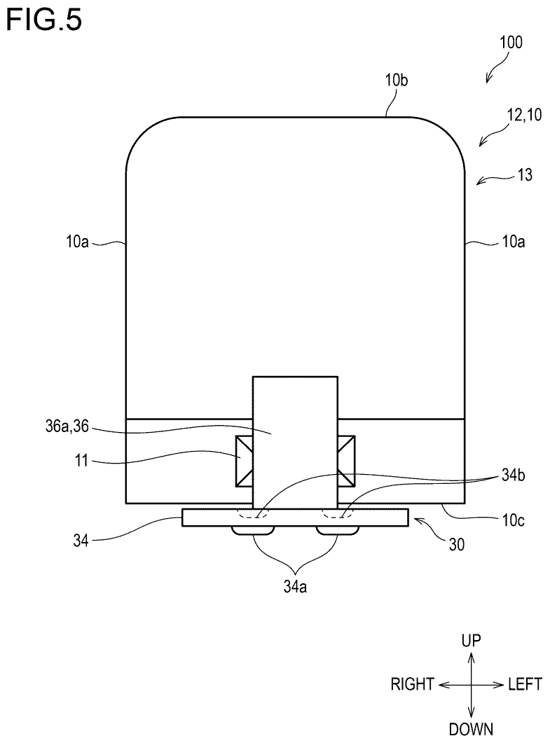

In the present embodiment, the lower surface of the mounting portion 34 is provided with a protruding portion 34a that protrudes downward from the lower surface of the mounting portion 34. As illustrated in FIGS. 4 and 5, in one mounting portion 34, two protruding portions 34a are provided so as to be separated from each other in the left-right direction. A protruding length of the protruding portion 34a (a dimension in the height direction to a lower end of the protruding portion 34a with respect to the lower surface of the mounting portion 34) is smaller than a thickness (dimension in height direction) of the protruding portion 34a.

In addition, as illustrated in FIGS. 1 and 6, the upper surface of the mounting portion 34 is provided with a depressed portion 34b that is depressed downward from the upper surface of the mounting portion 34. In one mounting portion 34, two depressed portions 34b are provided so as to be separated from each other in the left-right direction. A depth of the depressed portion 34b (a dimension in the height direction to a bottom surface of the depressed portion 34b with respect to the upper surface of the mounting portion 34) is smaller than the thickness of the mounting portion 34. In addition, in the present embodiment, the protruding portion 34a and the depressed portion 34b partially or entirely overlap with each other when viewed from the height direction. Furthermore, a center of the protruding portion 34a and a center of the depressed portion 34b coincide with each other when viewed from the height direction.

When joining the mounting portion 34 and the substrate to each other by soldering, for example, the joining can be performed as follows. A leading end (lower end) or a leading end surface (lower surface) of the protruding portion 34a and the substrate are brought into direct point contact or surface contact with each other and a lower surface of the mounting portion 34 (a partial surface region other than a part where the protruding portion 34a is provided) is indirectly joined to the substrate via solder. In addition, the solder may cover the upper surface of the mounting portion 34. At this point, due to solder being arranged in the depressed portion 34b of the upper surface of the mounting portion 34, the solder and the mounting portion 34 are joined more strongly.

In the present embodiment, the mounting portion 34 is integrally formed so as to be continuous with the erected portion 36 and the terminal 30 is bent between the mounting portion 34 and the erected portion 36. In the present embodiment, a bent portion located between the erected portion 36 and the mounting portion 34 is disposed outside the base portion 10 and is exposed from the base portion 10. An angle formed by a part of the terminal 30 from the mounting portion 34 to the erected portion 36 is equal to 90 degrees, larger than 90 degrees, or smaller than 90 degrees.

In the present embodiment, a portion of the terminal 30, particularly the first terminal 30a, which is exposed from the base portion 10 (i.e., the exposed end portion 30c), has two bent portions and is formed in a Z-shape. In addition, the exposed end portion 30c of the second terminal 30b has three bent portions, all of which are exposed from the base portion 10.

As illustrated in FIG. 3, approximately the entire embedded end portion 30d is embedded in the bottom portion 17 and a part of the embedded end portion 30d is embedded in the case portion 13. The embedded end portion 30d according to the present embodiment extends to below the accommodating portion 16 and one end portion of the embedded end portion 30d (one end portion on the opposite side to the mounting portion 34) is arranged inside the accommodating portion 16.

As illustrated in FIG. 2, a side closer to one end than the embedded portion 38 (opposite side to a side connected to the mounting portion 34) of the embedded end portion 30d in the first terminal 30a is bifurcated and the bifurcated portion is closed and becomes one further on a side closer to one end than the bifurcated portion. In other words, a part (annular portion 30d1) of the embedded end portion 30d has an annular shape. A dimension in the left-right direction of the annular portion 30d1 is larger than a dimension in the left-right direction of the embedded portion 38. A dimension in the left-right direction of a part (narrow width portion 30d2) on a side closer to one end than the annular portion 30d1 is smaller than the dimension in the left-right direction of the annular portion 30d1. The narrow width portion 30d2 protrudes upward in the middle, and a part of the narrow width portion 30d2 is arranged inside the accommodating portion 16. In addition, the embedded portion 38, the annular portion 30d1, and a part of the narrow width portion 30d2 are formed as one continuous plate member, and respective upper surfaces and lower surfaces of the embedded portion 38, the annular portion 30d1, and a part of the narrow width portion 30d2 are arranged on same planes.

The embedded end portion 30d in the second terminal 30b includes a part (wide width portion 30d3) arranged on an opposite side to the mounting portion 34 across the embedded portion 38 and a folded portion 30d4 that is one end portion of the embedded end portion 30d continuous from the wide width portion 30d3. In other words, the folded portion 30d4 and the embedded portion 38 branch from the wide width portion 30d3. The second terminal 30b protrudes upward at the boundary between the folded portion 30d4 and the wide width portion 30d3 and the folded portion 30d4 is arranged inside the accommodating portion 16.

The covering portion 11 refers to a portion in the base portion 10 that extends from the outer surface of the base portion 10 (body portion 12) and covers a part of or all of the outer surface of the exposed end portion 30c. As illustrated in FIG. 3, a portion excluding the covering portion 11 in the base portion 10 is called the body portion 12. In the present embodiment, the body portion 12 and the covering portion 11 are integrally formed in a seamless manner. In this case, the outer surface of the base portion 10 from which the covering portion 11 extends is, more specifically, the outer surface of the base portion 10 from which each of the terminals 30 protrudes. In other words, the outer surface of the base portion 10 from which the covering portion 11 extends is preferably the side surface 10a or the bottom surface 10c of the base portion 10. In the present embodiment, the covering portion 11 extends from a surface facing forward or rearward that is the side surface 10a of the base portion 10.

The covering portion 11 covering at least a part of a periphery of a base end in the exposed end portion 30c means that the covering portion 11 covers, with respect to a part on a side of the base end in the exposed end portion 30c, at least a part in a radial direction of the part in the exposed end portion 30c. In this case, the radial direction of the exposed end portion 30c (terminal 30) refers to a direction on a lateral cross section of the exposed end portion 30c (terminal 30) (cross section when cut perpendicularly with respect to the extension direction of the exposed end portion 30c) from a center toward a peripheral edge of the cross section. The term “radial direction” of the exposed end portion 30c (terminal 30) is used in the sense described above even when a cross-sectional shape of the terminal 30 is not a circle or a polygon. In other words, the covering portion 11 may cover the exposed end portion 30c in the entire radial direction so that the covering portion 11 circles a part on the base end side of the exposed end portion 30c. In addition, as in a second embodiment to be described later, the covering portion 11 may only cover a part in the radial direction with respect to a part on the base end side of the exposed end portion 30c. In other words, the covering portion 11 may only cover an upper side, a lower side, or a lateral side of the part on the base end side of the exposed end portion 30c.

Furthermore, in this case, a part on the base end side of the exposed end portion 30c specifically refers to a part of or all of the protruding portion 32. In the present embodiment, the covering portion 11 only covers a part on the base end side in the protruding portion 32 as will be described later. As an alternative to the present embodiment, while the covering portion 11 may further cover a part of or all of the bent portion between the protruding portion 32 and the erected portion 36 or a part of all of the erected portion 36, the bent portion or the erected portion 36 is preferably exposed from the covering portion 11 as will be described later.

As illustrated in FIG. 4 or 5, an area of the covering portion 11 when viewed in the protruding direction of the protruding portion 32 is preferably smaller than an area of the base portion 10 (body portion 12) when viewed in a same direction. More preferably, a width dimension (dimension in the left-right direction) of the covering portion 11 when viewed in the protruding direction of the protruding portion 32 is smaller than the width dimension of the base portion 10 (body portion 12) when viewed in the same direction. In addition, a thickness dimension (dimension in the height direction) of the covering portion 11 when viewed in the protruding direction of the protruding portion 32 is preferably smaller than a thickness dimension of the base portion 10 (body portion 12) when viewed in the same direction.

In addition, as illustrated in FIGS. 3 and 6, the covering portion 11 and the protruding portion 32 overlap with each other in an overlap region in a direction orthogonal to the protruding direction of the protruding portion 32 (left-right direction, up-down direction, or both). The covering portion 11 is preferably in close contact with the protruding portion 32 over the entire overlap region. In this case, the covering portion 11 and the protruding portion 32 being in close contact with each other over the entire overlap region includes the covering portion 11 and the protruding portion 32 being separated from each other in a very small part due to an unintentional void or the like.

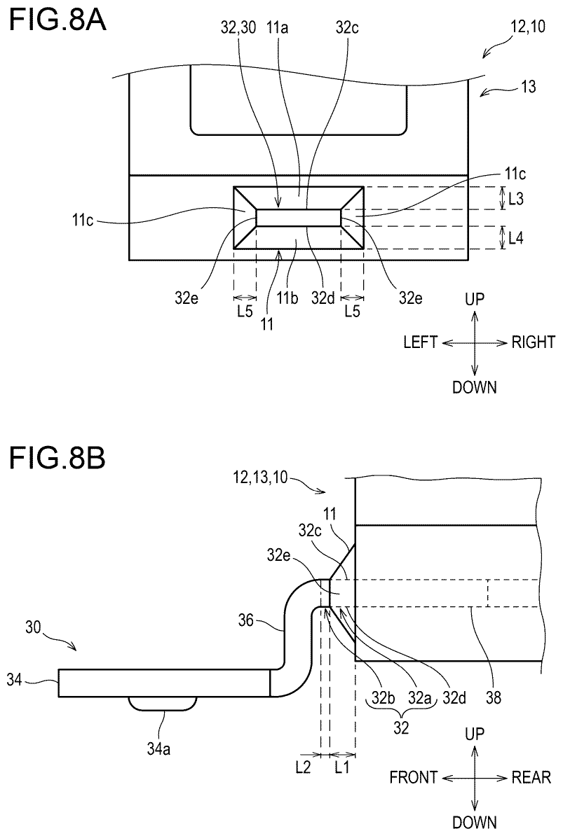

As illustrated in FIG. 8A, a shape of a cross section of the protruding portion 32 is a flattened shape that is thin in a transverse direction. The protruding portion 32 has a first main surface facing the transverse direction in the cross section of the protruding portion 32 and a second main surface that opposes the first main surface. The first main surface and the second main surface are covered by the covering portion 11. Hereinafter, a transverse direction in the cross section of the protruding portion 32 may be simply called a transverse direction of the protruding portion 32. In addition, a longitudinal direction in the cross section of the protruding portion 32 may be simply called a longitudinal direction of the protruding portion 32. Covering the first main surface and the second main surface with the covering portion 11 enables, when an external force in the transverse direction of the protruding portion 32 is applied to the electronic component 100, stress acting on the base portion 10 to be alleviated.

In this case, the cross section of the protruding portion 32 is a cross section viewed in the protruding direction of the protruding portion 32. While the shape of the cross section of the protruding portion 32 in the present embodiment is a rectangle elongated in the left-right direction, the cross-sectional shape is not limited thereto and may be a polygon or an ellipse that is flattened in a transverse direction. When the cross-sectional shape of the protruding portion 32 is a polygon, two surfaces face one transverse direction and the other transverse direction. In this case, a surface facing a predetermined direction refers to a normal vector of the surface having a predetermined direction component and includes, but not limited to, the normal vector of the surface being parallel to the predetermined direction. In the case of an ellipse, the first main surface or the second main surface refers to a surface region (a part of a peripheral surface) that is visible from the transverse direction of the protruding portion 32.

In the present embodiment, the transverse direction of the protruding portion 32 is the up-down direction. The first main surface may be a surface facing upward or a surface facing downward. Similarly, the second main surface may be a surface facing downward or a surface facing upward. In the present embodiment, the protruding portion 32 has an upper main surface 32c that faces upward, a lower main surface 32d that faces downward, and side end surfaces 32e to be described later that face the longitudinal direction (left-right direction). An area of the upper main surface 32c and the lower main surface 32d is larger than an area of each of the side end surfaces 32e. In the present embodiment, the first main surface will be described as the upper main surface 32c and the second main surface will be described as the lower main surface 32d.

As an alternative to the present embodiment, the transverse direction of the protruding portion 32 may be the left-right direction. In other words, the shape of the cross section of the protruding portion 32 may be a rectangle elongated in the up-down direction. In this case, the covering portion 11 covers surfaces facing the left-right direction in the outer surface of the protruding portion 32 as the first main surface and the second main surface.

The protruding portion 32 has a pair of side end surfaces 32e facing the longitudinal direction in the cross section of the protruding portion 32. Each of the pair of side end surfaces 32e is covered by the covering portion 11. Accordingly, when an external force in the longitudinal direction is applied to the electronic component 100, stress acting on the base portion 10 can be alleviated.

In the present embodiment, the covering portion 11 covers the pair of side end surfaces 32e in addition to the upper main surface 32c and the lower main surface 32d. The covering portion 11 according to the present embodiment includes a first covering portion 11a that covers the upper main surface 32c, a second covering portion 11b that covers the lower main surface 32d, and a third covering portion 11c that covers the side end surfaces 32e. Hereinafter, the first covering portion 11a, the second covering portion 11b, and the third covering portion 11c may be simply referred to as the covering portion 11. The first covering portion 11a, the second covering portion 11b, and the third covering portion 11c are integrally formed. In other words, an entire radial direction of the protruding portion 32 is covered by the covering portion 11 that is continuous in a circumferential direction and the covering portion 11 has no gaps separated in the circumferential direction of the protruding portion 32. Accordingly, when an external force is applied to the electronic component 100 and the protruding portion 32 is displaced, the covering portion 11 can readily follow the protruding portion 32. As an alternative to the present embodiment, gaps separated from each other in the circumferential direction of the protruding portion 32 may be provided between the first covering portion 11a, the second covering portion 11b, and the third covering portion 11c. Accordingly, the first covering portion 11a, the second covering portion 11b, and the third covering portion 11c can follow the displacement of the protruding portion 32 independently of each other.

As an alternative to the present embodiment, the upper main surface 32c and the lower main surface 32d may be entirely exposed from the covering portion 11 and only the pair of side end surfaces 32e may be covered by the covering portion 11. When the transverse direction of the protruding portion 32 is the up-down direction as in the present embodiment, only the surfaces that face the left-right direction in the outer surface of the protruding portion 32 may be covered by the covering portion 11, and when the transverse direction of the protruding portion 32 is the left-right direction, only the surfaces that face the up-down direction in the outer surface of the protruding portion 32 may be covered by the covering portion 11

As illustrated in FIG. 8B, the outer surface of the protruding portion 32 includes a covered region 32a and an exposed region 32b. The covered region 32a is a portion on a base end side of the protruding portion 32 and is covered by the covering portion 11. The exposed region 32b is flat. The exposed region 32b continues from the covered region 32a and is arranged on side closer to a leading end than the covered region 32a. Accordingly, when forming the base portion 10 by injection molding, since a surface of the injection molding mold and a flat surface of the exposed region 32b of the protruding portion 32 are aligned, leakage of resin from inside the injection molding mold is favorably suppressed. In addition, since a part of the terminal from the protruding portion 32 to the erected portion 36 readily deform under the external force applied to the electronic component 100 due to a part of the leading end of the protruding portion 32 being exposed from the covering portion 11, stress applied to the base portion 10 can be alleviated.

The covered region 32a or the exposed region 32b refers to a region that is a part of or all of the outer surface of the protruding portion 32. In this case, since the protruding portion 32 does not include the bent portion of the boundary between the protruding portion 32 and the erected portion 36, the outer surface of the protruding portion 32 is flat when the cross-sectional shape of the protruding portion 32 is a polygon such as a rectangle.

The exposed region 32b refers to a partial surface region that continues from the covered region 32a and arranged on a side closer to the leading end than the covered region 32a. In other words, the exposed region 32b and the covered region 32a overlap with each other when viewed from the protruding direction of the protruding portion 32. When the upper main surface 32c is covered by the covering portion 11 and the entire side end surfaces 32e including the base ends are exposed from the covering portion 11 as in the second embodiment to be described later, the exposed region 32b is a partial surface region on the leading end side of the upper main surface 32c and does not include a surface region on the base end side of the side end surfaces 32e.

The exposed region 32b being flat means that the exposed region 32b is an approximately flat surface and does not require the exposed region 32b being a completely flat surface. A part of the exposed region 32b may be slightly curved. The exposed region 32b being flat means that a part of or all of the exposed region 32b is flat. In particular, the exposed region 32b in the first main surface (upper main surface 32c) and the second main surface (lower main surface 32d) is preferably flat. Furthermore, preferably, the exposed region 32b in the side end surfaces 32e is also flat.

Furthermore, a dimension L1 (also referred to as a cover length) of the covered region 32a in the protruding direction of the protruding portion 32 is preferably larger than a dimension L2 of the exposed region 32b in the protruding direction of the protruding portion 32. Accordingly, when an external force is applied to the electronic component 100, stress applied to the base portion 10 from the protruding portion 32 is sufficiently alleviated. In addition, sufficiently reducing the length of the entire protruding portion 32 enables the dimension of the exposed end portion 30c in the protruding direction of the protruding portion 32 to be kept small.

In addition, the cover length of the covered region 32a on the first main surface (upper main surface 32c) may be equal to, larger than, or smaller than the cover length of the covered region on the second main surface (lower main surface 32d). When the cover length of the covered region 32a on the upper main surface 32c is larger than the cover length of the covered region 32a on the lower main surface 32d, since the covering portion 11 (second covering portion 11b) that covers the lower main surface 32d is less likely to inhibit a displacement of the bent portion on the boundary between the protruding portion 32 and the erected portion 36, the bent portion can be readily displaced. In addition, an injection molding mold that covers a lower side of the electronic component 100 during injection molding can readily cover a periphery of the protruding portion 32 and has a shape that is superior in terms of manufacturing suitability. On the other hand, when the cover length of the covered region 32a on the lower main surface 32d is larger than the cover length of the covered region 32a on the upper main surface 32c, a leading end of the second covering portion 11b is arranged in a vicinity of the bent portion on the boundary between the protruding portion 32 and the erected portion 36. Therefore, when an external force is applied to the electronic component 100, stress concentrates on the leading end, displacement of the bent portion on the boundary between the protruding portion 32 and the erected portion 36 is promoted, and a deformation of straight portions such as the protruding portion 32 is prevented. In addition, when the cover length of the covered region 32a on the upper main surface 32c is equal to the cover length of the covered region 32a on the lower main surface 32d, the exposed region 32b on the upper main surface 32c and the exposed region 32b on the lower main surface 32d overlap with each other when viewed in the transverse direction of the protruding portion 32. Such a configuration facilitates manufacturing because the protruding portion 32 is gripped equally in the up-down direction by a mold covering the upper side and a mold covering the lower side of the electronic component 100 used during injection molding.

When the cover length of a part of the covering portions 11 that covers a part in the radial direction of the protruding portion 32 and the cover length of another part of the covering portions 11 that covers another part in the radial direction of the protruding portion 32 differ from each other, leading ends of the covering portion 11 with different cover lengths may be smoothly continuous or connected discontinuously so as to have a step in the protruding direction of the protruding portion 32.

In addition, the cover length of the covered region 32a on the first main surface (upper main surface 32c) or the second main surface (lower main surface 32d) may be equal to, larger than, or smaller than the cover length of the covered region 32a on the side end surfaces 32e.

As an alternative to the present embodiment, all of the outer surface of the protruding portion 32 including the leading end may be covered by the covering portion 11 and all of the outer surface may be the covered region 32a.

In the present embodiment, as illustrated in FIGS. 6 and 8B, at least a part of the covering portion 11 is thinner from a base end toward a leading end. If the covering portion 11 is thinner from the base end toward the leading end, stiffness of the covering portion 11 decreases gradually or in multiple stages from the base end toward the leading end while flexibility of the covering portion 11 increases gradually or in multiple stages from the base end toward the leading end. Accordingly, the stress applied to the covering portion 11 when an external force is applied to the electronic component 100 is dispersed throughout the entire covering portion 11 or at a plurality of locations of the covering portion 11 from the leading end to the base end.

At least a part of the covering portion 11 refers to at least a part in the radial direction in the covering portion 11 arranged in the periphery of the protruding portion 32 being thinner from the base end toward the leading end. In other words, a part of the radial direction in the covering portion 11 arranged in the periphery of the protruding portion 32 is thinner from the base end toward the leading end while a thickness of other parts may be the same from the base end toward the leading end.

In this case, the covering portion 11 being thinner from the base end toward the leading end refers to the thickness of the covering portion 11 decreasing in multiple stages or continuously from the base end toward the leading end of the covering portion 11. In other words, the outer surface of the covering portion 11 may be an inclined surface with respect to the protruding direction of the protruding portion 32 as in the present embodiment or a stepped surface. In addition, the inclined surface of the outer surface of the covering portion 11 may be flat or a curved surface that bulges in a dome shape or a curved surface that is depressed toward the protruding portion 32 when viewed from the up-down direction or the left-right direction.

As illustrated in FIG. 8A, the thickness of the covering portion 11 in this case refers to a thickness in a direction connecting the center of the terminal and an outer edge of the covering portion 11 as viewed from the protruding direction of the protruding portion 32 or a distance between an inner edge on the side of each terminal 30 and an outer edge on an opposite side to the side of the terminal 30 in the covering portion 11. For example, a thickness on the base end side (maximum thickness) of the covering portion 11 (first covering portion 11a, second covering portion 11b, or third covering portion 11c) according to the present embodiment is a dimension L3, L4, or L5 shown in FIG. 8A.

As an alternative to the present embodiment, a thickness from the base end toward the leading end may be the same or the thickness may increase from the base end toward the leading end in a part of or all of the covering portion 11.

In the present embodiment, as illustrated in FIGS. 6, 8A, and 8B, each part of the covering portion 11 that covers the first main surface (upper main surface 32c), the second main surface (lower main surface 32d), and the pair of side end surfaces 32e is thinner from the base end toward the leading end. In other words, the first covering portion 11a, the second covering portion 11b, and the third covering portion 11c are thinner from the base end toward the leading end. When the upper main surface 32c, the lower main surface 32d, and the side end surfaces 32e are covered by the covering portion 11 as in the present embodiment, the thickness of the covering portion 11 is assumed to refer to, particularly, a thickness of a portion overlapping with the protruding portion 32 in the transverse direction or the longitudinal direction of the protruding portion 32.

As illustrated in FIG. 8B, the thickness of the covering portion 11 at the base end of the covering portion 11 is equal to or larger than the dimension of the covering portion 11 in the protruding direction of the protruding portion 32. Accordingly, stiffness of the covering portion 11 can be sufficiently reduced from the base end toward the leading end while reducing the dimension of the protruding portion 32 in the protruding direction of the protruding portion 32. In addition, since the thickness of the covering portion 11 at the base end of the covering portion 11 is sufficiently large, a variation in stiffness of the base portion 10 at the boundary between the covering portion 11 and the body portion 12 can be made small and, proportionally, stress concentrating on the boundary can be alleviated.

The thickness of the covering portion 11 may be equal to or larger than the dimension of the covering portion 11 in the protruding direction of the protruding portion 32 only in a part of the covering portion 11 viewed in the radial direction of the protruding portion 32 or the thickness of the covering portion 11 may be smaller than the dimension of the covering portion 11 in the protruding direction in other parts. Alternatively, as in the present embodiment, the thickness of the covering portion 11 may be equal to or larger than the dimension of the covering portion 11 in the protruding direction of the protruding portion 32 in all of the covering portion 11 viewed in the radial direction of the protruding portion 32.

When the covering portion 11 is continuously thinner from the base end toward the leading end, the surface of the covering portion 11 is an inclined surface that is arranged inclined with respect to the protruding direction of the protruding portion 32. The inclination (hereinafter, also referred to as an inclination angle) of the inclined surface with respect to the protruding direction is equal to or larger than 45 degrees.

As an alternative to the present embodiment, the thickness of the covering portion 11 at the base end of the covering portion 11 may be smaller than the dimension of the covering portion 11 in the protruding direction. In this case, the inclination angle of the inclined surface of the covering portion 11 is smaller than 45 degrees. Adopting such a configuration enables stiffness from the base end toward the leading end of the covering portion 11 to change more gradually and enables the covering portion 11 and the protruding portion 32 covered by the covering portion 11 to deform more flexibly under stress when an external force is applied to the electronic component 100.

As illustrated in FIG. 8A, at the base end of the covering portion 11, a thickness (dimension L3) of a part of the covering portions 11 (first covering portion 11a) that covers the first main surface is equal to or larger than a thickness (dimension L5) of another part of the covering portions 11 (third covering portion 11c) that covers the side end surfaces 32e. Since the main surface that is a surface facing the transverse direction of the protruding portion 32 has an area larger than the side end surfaces 32e, when an external force is applied to the electronic component 100, stress applied to the entire first covering portion 11a becomes larger than stress applied to the entire third covering portion 11c. Due to the thickness of the first covering portion 11a being equal to or larger than the thickness of the third covering portion 11c, stress that is applied to the covering portion 11 covering the first main surface can be alleviated more favorably.

In this case, the surface expected to be subjected to greater stress between the two main surfaces (upper main surface 32c and lower main surface 32d) facing the transverse direction of the protruding portion 32 can be considered the first main surface. In other words, the first main surface may be the upper main surface 32c or the lower main surface 32d. In addition, a thickness (dimension L4) of a part of the covering portions 11 (second covering portion 11b) that covers the second main surface is equal to or larger or smaller than the thickness (dimension L5) of the third covering portion 11c.

As an alternative to the present embodiment, the thickness of the part of the covering portions 11 that covers the first main surface may be smaller than the thickness of the other part of the covering portions 11 that covers the side end surfaces 32e. In this case, stress that is applied to the third covering portion 11c can be alleviated more favorably. The configuration described above may be adopted when an external force is expected to be applied to the electronic component 100 along the longitudinal direction of the protruding portion 32.

At the base end of the covering portion 11, the thickness of the part of the covering portions 11 (first covering portion 11a) that covers the first main surface is equal to or larger than the thickness of the part of the covering portions 11 (second covering portion 11b) that covers the second main surface. Accordingly, sufficient thickness can be imparted to the first covering portion 11a and the second covering portion 11b in accordance with the stress applied to the first covering portion 11a and the second covering portion 11b when an external force is applied to the electronic component 100.

In this case, the first main surface can be considered the main surface covered by the part of the covering portions 11 where greater stress concentrates between the respective covering portions 11 (the first covering portion 11a and the second covering portion 11b) that cover the main surfaces facing the transverse direction of the protruding portion 32. For example, if the greatest stress concentrates on a part of the first covering portion 11a when an external force is applied to the electronic component 100, the upper main surface 32c can be considered the first main surface, and when the greatest stress concentrates on a part of the second covering portion 11b, the lower main surface 32d can be considered the first main surface. In this manner, stress applied to the covering portion 11 from each of the terminals 30 can be sufficiently received by the covering portion 11 that covers the first main surface.

Alternatively, the second main surface may be considered the main surface covered by the part of the covering portions 11 where greater stress concentrates. In this manner, since the protruding portion 32 (terminal 30) and the thick-walled covering portion 11 that covers the first main surface are in close contact with each other, as stress is applied from the protruding portion 32 toward the thin-walled covering portion 11 that covers the first main surface, the stiffness of the thick-walled covering portion 11 can reduce the stress from the protruding portion 32 to the thin-walled covering portion 11.

When the first covering portion 11a and the second covering portion 11b are continuously thinner from the base end toward the leading end, the inclination angle of the flat inclined surface of the first covering portion 11a may be equal to or larger than the inclination angle of the inclined surface of the second covering portion 11b.

As illustrated in FIG. 8A, at the base end of the covering portion 11, the thickness of parts of the covering portion 11 (first covering portion 11a and second covering portion 11b) that cover the first main surface and the second main surface is equal to or larger than the dimension of the protruding portion 32 (thickness dimension of the protruding portion 32) in the transverse direction of the protruding portion 32. Accordingly, when the electronic component 100 is subjected to an external force, the first covering portion 11a and the second covering portion 11b can sufficiently support the protruding portion 32.

In addition, the thickness of parts of the covering portion 11 that cover the first main surface and the second main surface is preferably equal to or smaller than the dimension of the protruding portion 32 (width dimension of the protruding portion 32) in the longitudinal direction of the protruding portion 32. The reason for this is to impart sufficient flexibility to the covering portion 11 for following the protruding portion 32 that is displaced or deformed under an external force.

As an alternative to the present embodiment, the dimension of the protruding portion 32 in the transverse direction of the protruding portion 32 may be larger than the thickness of parts of the covering portion 11 that covers the first main surface and the second main surface at the base end of the covering portion 11. Sufficiently increasing the dimension of the protruding portion 32 in the transverse direction of the protruding portion 32 and increasing the stiffness of the protruding portion 32 makes the protruding portion 32 less likely to deform.

Therefore, the stress from the protruding portion 32 to the covering portion 11 in close contact with the protruding portion 32 when an external force is applied to the electronic component 100 is applied evenly from the base end to the leading end of the protruding portion 32.

As illustrated in FIG. 4, the periphery of the covering portion 11 when viewed from the protruding direction of the protruding portion 32 is surrounded by the outer surface of the base portion 10. In other words, the outer edge of the covering portion 11 is arranged inside the outer edge of the base portion 10 when viewed from the protruding direction. That is, the outer edge of the covering portion 11 and the outer edge of the base portion 10 are separated from each other when viewed from the protruding direction of the protruding portion 32. In addition, the thickness of the covering portion 11 is sufficiently smaller than the distance from a center of the protruding portion 32 to the outer edge of the base portion 10 when viewed from the protruding direction of the protruding portion 32. For example, the thickness of the first covering portion 11a (refer to FIG. 8A) or the second covering portion 11b (refer to FIG. 8A) is smaller than the distance from the center of the protruding portion 32 to the top surface 10b of the base portion 10 when viewed from the protruding direction of the protruding portion 32. In addition, the thickness of the third covering portion 11c (refer to FIG. 8A) is smaller than the distance from the center of the protruding portion 32 to the side surface 10a of the base portion 10 when viewed from the protruding direction of the protruding portion 32.

Due to the periphery of the covering portion 11 being surrounded by the outer surface of the base portion 10 when viewed from the protruding direction of the protruding portion 32 and the covering portion 11 extending from a part of the outer surface of the base portion 10, the thickness of the covering portion 11 is sufficiently smaller than the dimension of the base portion 10. Accordingly, the covering portion 11 can have sufficient flexibility for following the deforming protruding portion 32 if the protruding portion 32 deforms when the electronic component 100 is subjected to an external force.

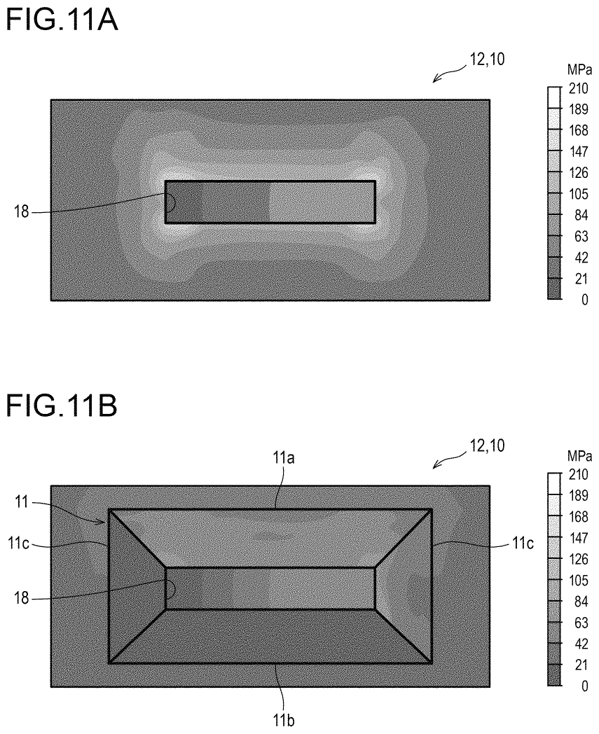

Alleviation of stress to the base portion 10 in the periphery of each of the terminals 30 (particularly, the embedded end portion 30d including the embedded portion 38) when an external force is applied to the electronic component 100 according to the present embodiment will now be described using FIGS. 11A and 11B. FIGS. 11A and 11B illustrate a vicinity of where each of the terminals 30 embedded in a frame protrudes. The shading within the frame represents a magnitude of stress applied to the portion in question.

A three-dimensional shape model simulating the electronic component 100 according to the present embodiment was created and stress applied to the base portion 10 was determined by the finite element method with respect to the three-dimensional model. In addition, in order to compare with stress applied to the base portion 10 in the electronic component 100, a three-dimensional shape model simulating an electronic component (referred to as a contrast electronic component) with the base portion 10 that has only the body portion 12 without the covering portion 11 was created and the stress was determined. The three-dimensional shape model simulating the electronic component 100 and the three-dimensional shape model simulating the contrast electronic component have the same shape except for the presence or absence of the covering portion 11. Material constants such as density and Young's modulus and the like for the respective members that constitute the electronic component 100 and the contrast electronic component and a solder and a glass plate to be described later were entered for the material types described above. Three-dimensional shape models were created by elementally dividing the electronic component 100 and the contrast electronic component into tetrahedral elements. The electronic component 100 and the contrast electronic component were fixed to a substrate (a glass plate made of lime glass or the like) by soldering as described above. In other words, the electronic component 100 or the contrast electronic component and the solder share a contact, the solder and the substrate also share a contact, and the electronic component 100 or the contrast electronic component and the substrate also share a contact. The glass plate as the substrate had a square-shaped main surface. The glass plate had its peripheral side surfaces (side end surfaces) fixed.

Assuming that the electronic component 100 is to be pulled upward from the substrate, a computer simulation was used to calculate the stress applied to the base portion 10 when an external force in an upward orientation from bottom is applied to the electronic component 100. Specifically, the stress when a force of 100 N was applied to the plug engagement protruding portion 13b (refer to FIG. 3) of the base portion 10 was calculated. The force of 100 N was assumed to be applied in a dispersed manner over the insertion surface 13b1 (refer to FIG. 3) and a lower surface (a surface facing downward and arranged between the insertion surface 13b1 and the engagement surface 13b2 (refer to FIG. 3)) of the plug engagement protruding portion 13b.

As shown in FIG. 11A, in the contrast electronic component, stress concentrated on a vicinity of each corner of an opening portion (terminal insertion portion 18) with a rectangular shape in a depressed portion formed when embedding each of the terminals 30 (embedded portion 38) in the body portion 12. Specifically, a maximum stress applied to the portion was approximately 148 MPa. Note that the stress applied to the portion was a maximum value of the stress applied to the contrast electronic component. On the other hand, in the electronic component 100, stress was dispersed over the entire covering portion 11. Specifically, a rectangle-shaped hole (terminal insertion portion 18) is formed inside the covering portion 11 when viewed from the protruding direction of the protruding portion 32 due to penetration of each of the terminals 30 (protruding portion 32). As shown in FIG. 11B, the stress on the vicinity of the corners of the hole is smaller than the stress applied to the vicinity of the corners of the depressed portion in the body portion 12 in the contrast electronic component and, specifically, the maximum stress applied to the portion was 73 MPa. In addition, the stress applied to the vicinity of the corners of the hole was a maximum value of the stress applied to the electronic component 100. In other words, in the electronic component 100, the maximum value of the stress applied to the base portion 10 was reduced by approximately 51% as compared to the contrast electronic component. Furthermore, in the electronic component 100, stress was also applied to a vicinity of edges (particularly, an edge arranged above and an edge arranged to the side) that constitute the hole when viewed from the protruding direction of the protruding portion 32. In other words, it was confirmed that stress was applied in a dispersed manner to the first covering portion 11a (refer to FIG. 8A) and the third covering portion 11c (refer to FIG. 8A) in the electronic component 100.

### Second Embodiment

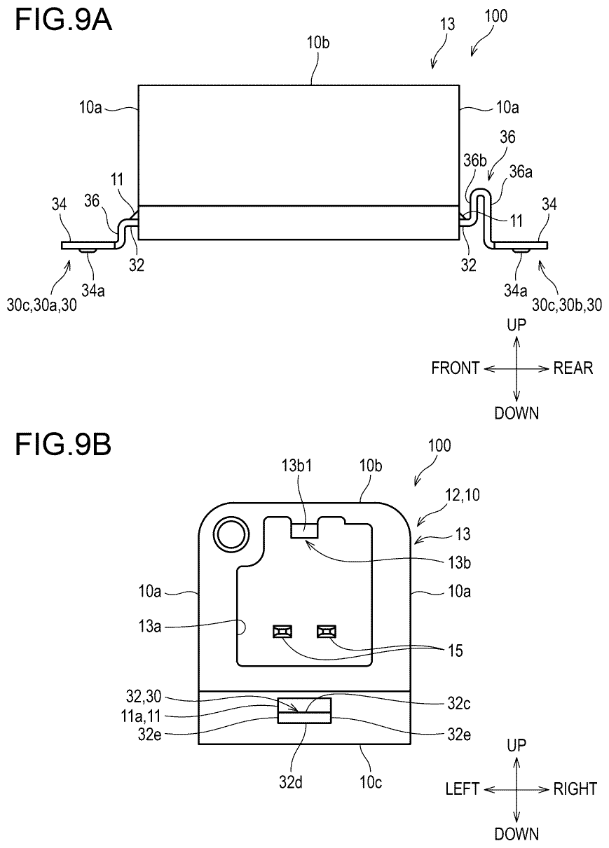

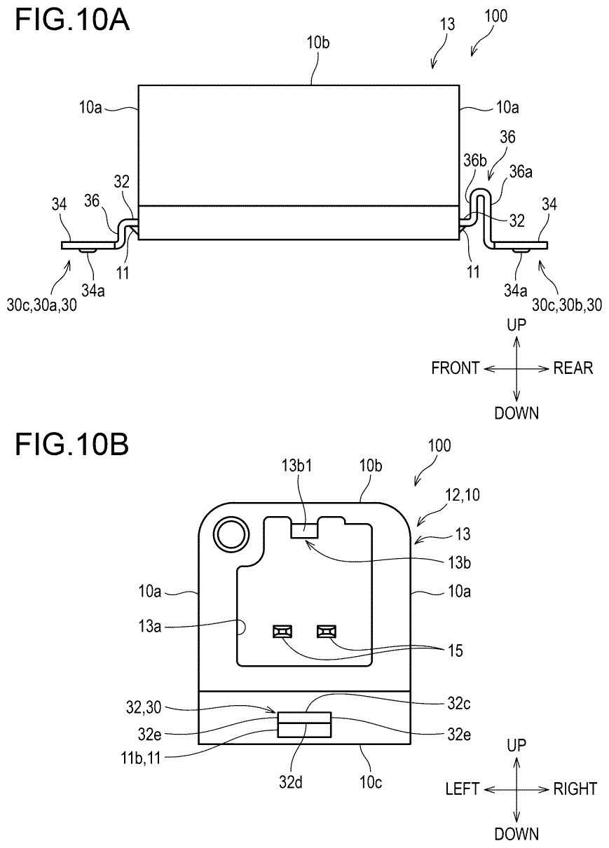

FIGS. 9A and 10A are side views showing an example of the electronic component 100 according to the present embodiment. FIGS. 9B and 10B are front views of the electronic component 100.

First, an overview of the electronic component 100 according to the present embodiment will be described.

As described above, the electronic component 100 according to the present embodiment includes the base portion 10 that has the accommodating portion 16 for accommodating an electronic element and the terminals 30 that have a part (embedded portion 38 to be described later) embedded in the base portion 10 and one end portion (exposed end portion 30c to be described later) protruding from the base portion 10 toward outside of the base portion 10. The base portion 10 has the covering portion 11 that extends from an outer surface of the base portion 10 and covers at least a part of a periphery of a base end in the one end portion (exposed end portion 30c).

Next, the electronic component 100 according to the present embodiment will be described in detail.

The electronic component 100 according to the present embodiment differs from the first embodiment described above in that a part of a periphery of the base end in one end portion (exposed end portion 30c) is covered by the covering portion 11 and another part of the periphery of the base end in the exposed end portion 30c is exposed from the covering portion 11. For example, a direction in which an external force is likely to be applied to the electronic component 100 can be predicted, in which case the covering portion 11 can be arranged in a part where stress concentrates in the radial direction of the protruding portion 32 while the covering portion 11 can be prevented from being arranged at other parts (the other parts can be exposed from the covering portion 11). For example, when it is expected that an upward external force from below is to be applied to the electronic component 100, the covering portion 11 may be arranged only on the upper side of the protruding portion 32 as will be described later.

Accordingly, when an external force is applied to the electronic component 100, each of the terminals 30 is pushed against the base portion 10 including the covering portion 11. Therefore, while stress is applied to the base portion 10, since providing the covering portion 11 cases the stress to be applied to the covering portion 11 in a dispersed manner, stress concentration on a part of the base portion 10 can be avoided.

In addition, the covering portion 11 may not be arranged in a part where stress concentrates in the radial direction of the protruding portion 32 (the part may be exposed) and the covering portion 11 may be arranged in another part that opposes the part across the protruding portion 32. For example, when it is expected that an upward external force from below is to be applied to the electronic component 100, the covering portion 11 may be arranged only on the lower side of the protruding portion 32 as will be described later. Accordingly, the protruding portion 32 can be prevented from being displaced or deformed when the covering portion 11 in close contact with the protruding portion 32 receives an external force.

Furthermore, an amount of resin used in manufacture can be reduced by arranging the covering portion 11 only in necessary portions in the periphery of the base end of the protruding portion 32. In addition, the covering portion 11 is prevented from inhibiting the deformation of the protruding portion 32 by not covering the entire periphery of the base end of the protruding portion 32 with the covering portion 11. Therefore, the protruding portion 32 can deform moderately to disperse stress when the electronic component 100 is subjected to an external force.

As illustrated in FIGS. 9A and 9B, an example of the present embodiment is an aspect in which only the base end of the first main surface (upper main surface 32c) is covered by the covering portion 11 (first covering portion 11a) and the entireties of the second main surface (lower main surface 32d) and the pair of side end surfaces 32e are exposed from the covering portion 11.

As illustrated in FIGS. 10A and 10B, an example of the present embodiment is an aspect in which only the base end of the second main surface (lower main surface 32d) is covered by the covering portion 11 (second covering portion 11b) and the entireties of the first main surface (upper main surface 32c) and the pair of side end surfaces 32e are exposed from the covering portion 11. As illustrated in FIGS. 9B and 10B, the side end surfaces 32e of the protruding portion 32 and side end surfaces of the covering portion 11 are arranged on a same plane. As an alternative to the present embodiment, the side end surfaces of the covering portion 11 may be arranged outward in the left-right direction than the side end surfaces 32e of the protruding portion 32 or arranged inward in the left-right direction.

Instead of the examples represented by FIGS. 9A to 10B, the base end of any one or both of the pair of side end surfaces 32e in the protruding portion 32 may be covered by the covering portion 11 and an entirety of another surface (first main surface or second main surface) may be exposed from the covering portion 11. Otherwise, the base end of a surface of any part of the first main surface, the second main surface, or the pair of side end surfaces 32e may be covered by the covering portion 11 and the base end of a remaining surface may be exposed from the covering portion 11.

In addition, the electronic component 100 according to the present embodiment has the following features in a similar manner to the electronic component 100 according to the first embodiment.

The outer surface of the protruding portion 32 includes the covered region 32a that is partially covered by the covering portion 11 on the base end side and the flat exposed region 32b that continues from the covered region 32a and arranged on a side closer to the leading end than the covered region 32a.

At least a part of the covering portion 11 is thinner from the base end toward the leading end.

The thickness of the covering portion 11 at the base end of the covering portion 11 is equal to or larger than the dimension of the covering portion 11 in the protruding direction.

The present invention is not limited to the embodiments described above and includes aspects of various modifications, improvements, and the like insofar as the object of the present invention is achieved.

The modifications described below may be appropriately combined with one another.

While the electronic component 100 according to the first embodiment or the second embodiment is used by connecting a plug for connecting to an external system, the electronic component 100 is not limited thereto. The electronic element may only be connected to the terminals 30.

The embodiments described above cover the following technical ideas.
(1) An electronic component including a base portion having an accommodating portion that accommodates an electronic element and a terminal of which a part is embedded in the base portion and of which one end portion protrudes toward outside of the base portion from the base portion, wherein
the base portion has a covering portion that extends from an outer surface of the base portion and covers at least a part of a periphery of a base end in the one end portion.
(2) The electronic component according to (1), wherein
a part of the periphery of the base end in the one end portion is covered by the covering portion, and
another part of the periphery of the base end in the one end portion is exposed from the covering portion.
(3) The electronic component according to (1), wherein
the one end portion has a protruding portion that is positioned on a base end side of the one end portion and extends in a protruding direction of the one end portion,
a shape of a cross section of the protruding portion is a flattened shape that is thin in a transverse direction,
the protruding portion has a first main surface facing a transverse direction in the cross section of the protruding portion and a second main surface that opposes the first main surface, and
the first main surface and the second main surface are covered by the covering portion.
(4) The electronic component according to (3), wherein
the protruding portion has
   a pair of side end surfaces facing a longitudinal direction in the cross section of the protruding portion, and
each of the pair of side end surfaces is covered by the covering portion.
(5) The electronic component according to (4), wherein
an outer surface of the protruding portion includes
   a covered region which is a portion on a base end side of the protruding portion and is covered by the covering portion and
   an exposed region that continues from the covered region, is arranged on a side closer to a leading end than the covered region and is flat.
(6) The electronic component according to any one of (3) to (5), wherein at least a part of the covering portion is thinner from a base end toward a leading end.
(7) The electronic component according to (4) or (5), wherein each part of the covering portion that covers the first main surface, the second main surface, and the pair of side end surfaces is thinner from a base end toward a leading end.
(8) The electronic component according to (6) or (7), wherein a thickness of the covering portion at the base end of the covering portion is equal to or larger than a dimension of the covering portion in the protruding direction.
(9) The electronic component according to any one of (6) to (8) citing (4), wherein at the base end of the covering portion, a thickness of a part of the covering portion that covers the first main surface is equal to or larger than a thickness of another part of the covering portion that covers the side end surfaces.
(10) The electronic component according to any one of (6) to (9), wherein at the base end of the covering portion, a thickness of a part of the covering portion that covers the first main surface is equal to or larger than a thickness of a part of the covering portion that covers the second main surface.
(11) The electronic component according to any one of (6) to (10), wherein at the base end of the covering portion, a thickness of a part of the covering portion that covers the first main surface and the second main surface is equal to or larger than a dimension of the protruding portion in a transverse direction of the protruding portion.
(12) The electronic component according to any one of (7) to (11), wherein a periphery of the covering portion as viewed from the protruding direction is surrounded by the outer surface of the base portion.

1. An electronic component comprising a base portion having an accommodating portion that accommodates an electronic element and a terminal of which a part is embedded in the base portion and of which one end portion protrudes toward outside of the base portion from the base portion, wherein
the base portion has a covering portion that extends from an outer surface of the base portion and covers at least a part of a periphery of a base end in the one end portion.

2. The electronic component according to claim 1, wherein
a part of the periphery of the base end in the one end portion is covered by the covering portion, and
another part of the periphery of the base end in the one end portion is exposed from the covering portion.

3. The electronic component according to claim 1, wherein
the one end portion has a protruding portion that is positioned on a base end side of the one end portion and extends in a protruding direction of the one end portion,
a shape of a cross section of the protruding portion is a flattened shape that is thin in a transverse direction,
the protruding portion has a first main surface facing a transverse direction in the cross section of the protruding portion and a second main surface that opposes the first main surface, and
the first main surface and the second main surface are covered by the covering portion.

4. The electronic component according to claim 3, wherein
the protruding portion has
a pair of side end surfaces facing a longitudinal direction in the cross section of the protruding portion, and
each of the pair of side end surfaces is covered by the covering portion.

5. The electronic component according to claim 4, wherein
an outer surface of the protruding portion includes
a covered region which is a portion on a base end side of the protruding portion and is covered by the covering portion and
an exposed region that continues from the covered region, is arranged on a side closer to a leading end than the covered region and is flat.

6. The electronic component according to claim 4, wherein at least a part of the covering portion is thinner from a base end toward a leading end.

7. The electronic component according to claim 4, wherein each part of the covering portion that covers the first main surface, the second main surface, and the pair of side end surfaces is thinner from a base end toward a leading end.

8. The electronic component according to claim 6, wherein a thickness of the covering portion at the base end of the covering portion is equal to or larger than a dimension of the covering portion in the protruding direction.

9. The electronic component according to of claim 6, wherein at the base end of the covering portion, a thickness of a part of the covering portion that covers the first main surface is equal to or larger than a thickness of another part of the covering portion that covers the side end surfaces.

10. The electronic component according to claim 6, wherein at the base end of the covering portion, a thickness of a part of the covering portion that covers the first main surface is equal to or larger than a thickness of a part of the covering portion that covers the second main surface.

11. The electronic component according to claim 6, wherein at the base end of the covering portion, a thickness of a part of the covering portion that covers the first main surface and the second main surface is equal to or larger than a dimension of the protruding portion in a transverse direction of the protruding portion.

12. The electronic component according to of claim 7, wherein a periphery of the covering portion as viewed from the protruding direction is surrounded by the outer surface of the base portion.
